(19) United States
(12) Patent Application Publication
(10) Pub. No.: US 2020/0313004 A1
(43) Pub. Date: Oct. 1, 2020

(54) THIN FILM TRANSISTOR AND METHOD OF FORMING THE SAME, DISPLAY SUBSTRATE AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Zhiying BAO, Beijing (CN); Shijun WANG, Beijing (CN); Lu BAI, Beijing (CN)

(73) Assignees: BOE TECHNOLOGY GROUP CO., LTD., Beijing (CN); BEIJING BOE OPTOELECTRONICS TECHNOLOGY CO., LTD., Beijing (CN)

(21) Appl. No.: 15/777,339

(22) PCT Filed: Sep. 26, 2017
(86) PCT No.: PCT/CN2017/103381

§ 371 Date: May 18, 2018

(30) Foreign Application Priority Data
Feb. 16, 2017 (CN) 201710083390.7

(51) Int. Cl. H01L 29/786; H01L 27/12; H01L 29/66; G02F 1/1368

(52) U.S. Cl. CPC H01L 29/78696; H01L 27/1222; G02F 1/1368; H01L 29/78618; H01L 29/66742; H01L 27/1288

(57) ABSTRACT

A thin film transistor and a method of forming the same, a display substrate and a display device are provided. The thin film transistor includes: a source electrode, a drain electrode and an active layer on a base substrate, where the active layer includes a source electrode contact region configured to be in contact with the source electrode, a drain electrode contact region configured to be in contact with the drain electrode and a channel region between the source electrode contact region and the drain electrode contact region; a first conductive pattern, arranged at the channel region of the active layer and being in contact with the channel region of the active layer.

### CROSS-REFERENCE TO RELATED APPLICATION

The present application claims a priority of the Chinese patent application No. 201710083390.7 filed on Feb. 16, 2017, which is incorporated herein by reference in its entirety.

### TECHNICAL FIELD

The present disclosure relates to the field of display technology, and in particular to a thin film transistor and a method of forming the same, a display substrate and a display device.

### BACKGROUND

In the thin film transistor liquid crystal display (TFT-LCD) industry, the low-generation array substrate exposure equipment used in the industry generally has a low precision, therefore a thin film transistor (TFT) channel length L is relatively large and cannot be shortened. Because the magnitude of the on-state current of the TFT is in direct proportion to a width to length radio W/L of the TFT channel, the magnitude of the on-state current of the TFT may be small. As the pixel per inch (PPI) of the high-end display product becomes higher and higher, in order to meet the requirements of the charging rate of the display product, the magnitude of the on-state current of the TFT needs to be increased. Therefore, the channel width of the TFT needs to be designed to be relatively large, which seriously affects the aperture ratio of the display substrate, and causes the display substrate to have a relatively large load. As a result, the power consumption of the display device may be increased.

### SUMMARY

The objective of the present disclosure is to provide a thin film transistor and a method of forming the same, a display substrate and a display device, so as to increase the magnitude of the on-state current of the TFT and thus reduce the channel width of the TFT.

In view of this, the embodiments of the present disclosure are as follows.

In one aspect, a thin film transistor is provided in the present disclosure, including: a source electrode, a drain electrode and an active layer on a base substrate, where the active layer includes a source electrode contact region configured to be in contact with the source electrode, a drain electrode contact region configured to be in contact with the drain electrode and a channel region between the source electrode contact region and the drain electrode contact region; a first conductive pattern, arranged at the channel region of the active layer and being in contact with the channel region of the active layer.

Optionally, the thin film transistor further includes: a second conductive pattern, being in contact with the source electrode contact region of the active layer and spaced apart from the first conductive pattern; and/or a third conductive pattern, being in contact with the drain electrode contact region of the active layer and spaced apart from the first conductive pattern.

Optionally, a plurality of first conductive patterns is arranged at the channel region of the active layer in an array form.

Optionally, an extension direction of each of the first conductive patterns is parallel to a first direction from the source electrode to the drain electrode.

Optionally, a length of each of the first conductive patterns is smaller than a vertical distance between the source electrode and the drain electrode.

Optionally, the length of each of the first conductive patterns is Lx, and an interval between adjacent two first conductive patterns in the first direction is Ly, and a ratio of Ly to Lx is from 0.3 to 0.7.

Optionally, an extension direction of each of the first conductive patterns is not parallel to a first direction from the source electrode to the drain electrode; a projection length of each of the first conductive patterns in the first direction is Lx, and in an extension direction of each of the first conductive patterns, a projection interval between adjacent two first conductive patterns in the first direction is Ly, and a ratio of Ly to Lx is from 0.3 to 0.7.

Optionally, the first conductive pattern, the second conductive pattern and the third conductive pattern are metallic nanowires.

Optionally, the length of the first conductive pattern is smaller than 1000 nm.

Optionally, a diameter of a cross section of the first conductive pattern is smaller than 100 nm.

A display substrate is further provided in the present disclosure, including the above thin film transistor.

A display device is further provided in the present disclosure, including the above display substrate.

A method of forming a thin film transistor is further provided in the present disclosure, including: forming a source electrode, a drain electrode and an active layer on a base substrate, where the active layer includes a source electrode contact region configured to be in contact with the source electrode, a drain electrode contact region configured to be in contact with the drain electrode and a channel region between the source electrode contact region and the drain electrode contact region; forming a first conductive pattern arranged at the channel region of the active layer and being in contact with the channel region of the active layer.

Optionally, the forming the first conductive pattern further includes: coating a photoresist on the base substrate where the first conductive pattern is to be formed; transferring a pattern on a pattern plate onto the photoresist by an imprinting process, to form a photoresist reserved region and a photoresist unreserved region, where the photoresist unreserved region corresponds to the pattern; depositing a conductive layer including a first portion at the photoresist reserved region and a second portion at the photoresist unreserved region and in contact with the base substrate; and exposing and developing the photoresist, to remove the photoresist at the photoresist reserved region and the first portion of the photoresist and reserve the second portion of the photoresist, to form the first conductive pattern.

Optionally, the method further includes: forming a second conductive pattern and/or a third conductive pattern simultaneously with the first conductive pattern, where the second conductive pattern is in contact with the source electrode contact region of the active layer and spaced apart from the first conductive pattern, and the third conductive pattern is in contact with the drain electrode contact region of the active layer and spaced apart from the first conductive pattern.

The present disclosure has the following advantages.

According to the embodiments of the present disclosure, the TFT has the first conductive pattern in contact with the channel region of the active layer. The first conductive pattern may increase the electron transportation channels on the channel region and increase the electronic mobility of the channel region, thereby significantly shortening the TFT channel and increasing the magnitude of the on-state current of the TFT. As a result, the TFT may easily meet the requirements of the charging rate of the high-PPI display product, so the channel region of the TFT may be designed to be narrower, thereby improving the aperture ratio of the display substrate and reducing the power consumption thereof.

### BRIEF DESCRIPTION OF THE DRAWINGS

FIG. 1 is a schematic view of a channel region of a TFT in the related art;

FIG. 2 is a schematic view of a channel region of a TFT in some embodiments of the present disclosure;

FIG. 3 is a schematic view of a channel region of a TFT in some embodiments of the present disclosure;

FIG. 4 shows an effective interval between adjacent two conductive patterns and an effective length of a conductive pattern in some embodiments of the present disclosure;

FIG. 5 is a schematic view of a channel region of a TFT in some embodiments of the present disclosure;

FIG. 6 shows an effective interval between adjacent two conductive patterns and an effective length of a conductive pattern in some embodiments of the present disclosure; and

FIGS. 7-12 show a process of forming a conductive pattern and an active layer of the TFT in some embodiments of the present disclosure.

### DRAWING REFERENCES

1: source electrode; 2: drain electrode; 3: active layer; 41: first conductive pattern; 42: second conductive pattern; 43: third conductive pattern; 5: base substrate; 6: photoresist; 7: pattern plate; 8: conductive layer

### DETAILED DESCRIPTION OF THE EMBODIMENTS

In order to make the objects, the technical solutions and the advantages of the present disclosure more apparent, the present disclosure will be described hereinafter in a clear and complete manner in conjunction with the drawings and embodiments.

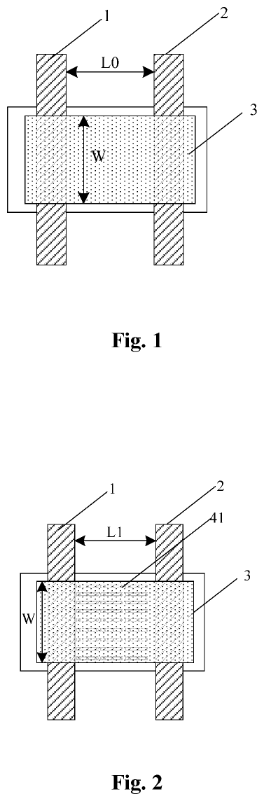

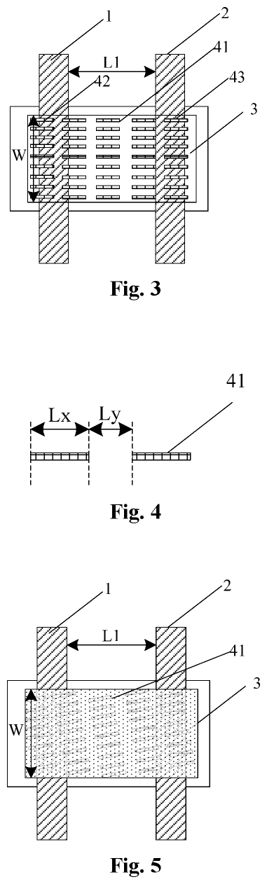

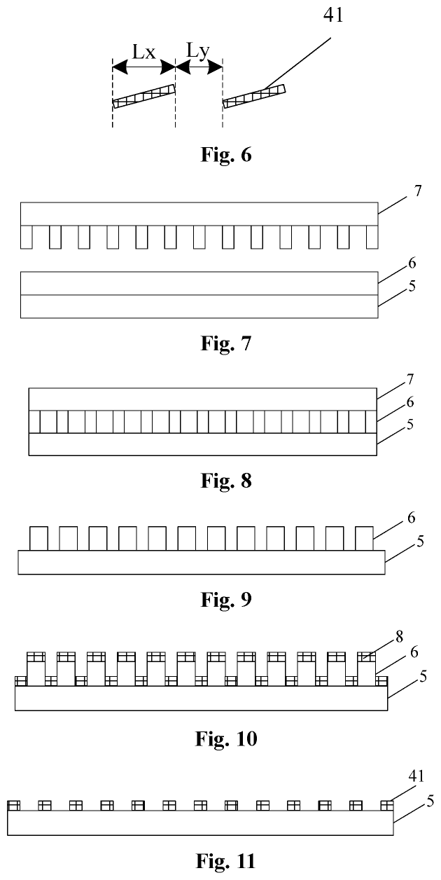

As shown in FIG. 1, the TFT in the related art includes a source electrode 1, a drain electrode 2 and an active layer 3 on a base substrate 5. The active layer 3 includes a source electrode contact region configured to be in contact with the source electrode 1, a drain electrode contact region configured to be in contact with the drain electrode 2 and a channel region between the source electrode contact region and the drain electrode contact region. The larger the width to length ratio W/L0 of the channel region, the larger the magnitude of the on-state current Ion of the TFT will be.

In the TFT-LCD industry, the low-generation array substrate exposure equipment used in the industry generally has a low precision, therefore the channel length L0 of the TFT is relatively large and cannot be shortened. Because the magnitude of the on-state current of the TFT is in direct proportion to the width to length radio W/L0 of the TFT channel, the magnitude of the on-state current of the TFT may be small.

In view of the above technical issue in the related art, a thin film transistor and a method of forming the same, a display substrate and a display device are provided in the embodiments of the present disclosure, so as to increase the magnitude of the on-state current of the TFT and thus reduce the channel width of the TFT.

### Embodiment I

A thin film transistor is provided in some embodiments of the present disclosure. As shown in FIG. 2, the thin film transistor includes: a source electrode 1, a drain electrode 2 and an active layer 3 on a base substrate 5, where the active layer 3 includes a source electrode contact region configured to be in contact with the source electrode 1, a drain electrode contact region configured to be in contact with the drain electrode 2 and a channel region between the source electrode contact region and the drain electrode contact region. As shown in FIG. 2, the thin film transistor further includes a first conductive pattern 41 which is arranged at least at the channel region of the active layer 3 and being in contact with the channel region of the active layer 3.

Because the first conductive pattern 41 is conductive, the first conductive pattern 41 may increase the electron transportation channels on the channel region and increase the electronic mobility of the channel region, thereby significantly shortening the TFT channel and increasing the magnitude of the on-state current of the TFT. As a result, the TFT may easily meet the requirements of the charging rate of the high-PPI display product, so the channel region of the TFT may be designed to be narrower, thereby improving the aperture ratio of the display substrate and reducing the power consumption thereof.

The first conductive pattern 41 may be arranged on or below the active layer 3, as long as being in contact with the channel region of the active layer 3. It should be noted that, each of the first conductive patterns 41 may be in contact with only a part of the channel region, such that the first conductive pattern 41 may not electrically connect the source electrode 1 to the drain electrode 2. For example, the two ends of the first conductive pattern 41 may not be arranged in the source electrode contact region and the drain electrode contact region respectively at the same time.

The shape of the first conductive pattern 41 is not limited, as long as the first conductive pattern 41 has an effective length in a first direction from the source electrode 1 to the drain electrode 2. One or more first conductive patterns 41 may be arranged at the channel region of the active layer 3.

In some embodiments of the present disclosure, as shown in FIG. 2, a plurality of first conductive patterns 41 may be arranged at the channel region of the active layer 3 in an array form, thereby increasing the electron transportation channels on the channel region and increasing the magnitude of the on-state current of the TFT.

The length of the channel region reduced by the first conductive pattern 41 is related to the effective length of the first conductive pattern 41 in the first direction. Optionally, an extension direction of each of the first conductive patterns 41 is parallel to the first direction from the source electrode 1 to the drain electrode 2, thereby the length of the channel region reduced by the first conductive pattern 41 is equal to the length of the first conductive pattern 41.

As shown in FIG. 4, the length of each of the first conductive patterns 41 is Lx, and an interval between adjacent two first conductive patterns 41 in the first direction is Ly. n first conductive patterns 41 are arranged at the channel region along the first direction. A vertical distance between the source electrode 1 and the drain electrode 2 is L1, where n is equal to or larger than 1. Due to the first conductive patterns 41, the parameter L0 used in calculating the width to length ratio W/L0 of the channel region may be reduced to L1−n*Lx. Obviously, L0 is reduced significantly. As such, the width to length ratio of the channel region is increased, so the magnitude of the on-state current of the TFT may be increased significantly, and the TFT may easily meet the requirements of the charging rate of the high-PPI display product. Therefore, the width W of channel region of the TFT may be designed to be smaller, thereby reducing the size of the TFT, improving the aperture ratio of the display substrate and reducing the power consumption thereof.

To be specific, the first conductive pattern 41 may be a nanoscale metallic wire, thereby significantly increasing the electronic mobility of the channel region. A diameter of a cross section of the first conductive pattern 41 may be smaller than 100 nm, and the length of the first conductive pattern 41 may be smaller than 1000 nm. Through massive data validation, when designing the first conductive layer 8, the ratio of Ly to Lx may be designed to be from 0.3 to 0.7. With such parameters, the electronic mobility of the channel region may be increased significantly.

### Embodiment II

A thin film transistor is provided in some embodiments of the present disclosure. As shown in FIG. 3, the thin film transistor includes: a source electrode 1, a drain electrode 2 and an active layer 3 on a base substrate 5, where the active layer 3 includes a source electrode contact region configured to be in contact with the source electrode 1, a drain electrode contact region configured to be in contact with the drain electrode 2 and a channel region between the source electrode contact region and the drain electrode contact region. As shown in FIG. 3, the thin film transistor further includes: a first conductive pattern 41 which is arranged at least at the channel region of the active layer 3 and being in contact with the channel region of the active layer 3; a second conductive pattern 42, being in contact with the source electrode contact region of the active layer 3 and spaced apart from the first conductive pattern 41; and/or a third conductive pattern 43, being in contact with the drain electrode contact region of the active layer 3 and spaced apart from the first conductive pattern 41.

Because the first conductive pattern 41 is conductive, the first conductive pattern 41 may increase the electron transportation channels on the channel region and increase the electronic mobility of the channel region, thereby significantly shortening the TFT channel and increasing the magnitude of the on-state current of the TFT. As a result, the TFT may easily meet the requirements of the charging rate of the high-PPI display product, so the channel region of the TFT may be designed to be narrower, thereby improving the aperture ratio of the display substrate and reducing the power consumption thereof.

Optionally, one of the second conductive pattern 42 and the third conductive pattern 43 is arranged, or both the second conductive pattern 42 and the third conductive pattern 43 are arranged. As shown FIG. 3, in some embodiments of the present disclosure, both the second conductive pattern 42 and the third conductive pattern 43 are arranged.

Because the second conductive pattern 42 is conductive, the second conductive pattern 42 at the source electrode contact region may be connected in parallel with the source electrode contact region, thereby reducing the resistance of the source electrode contact region. Because the third conductive pattern 43 is conductive, the third conductive pattern 43 at the drain electrode contact region may be connected in parallel with the drain electrode contact region, thereby reducing the resistance of the drain electrode contact region.

All of the first conductive pattern 41, the second conductive pattern 42 and the third conductive pattern 43 may be arranged on or below the active layer 3, or a part of them is arranged on the active layer 3 and rest is arranged below the active layer 3, as long as being in contact with the channel region of the active layer 3. It should be noted that, the first conductive patterns 41 may be in contact with only a part of the channel region and separated apart from the second conductive pattern 42 and the third conductive pattern 43, such that the first conductive pattern 41, the second conductive pattern 42 and the third conductive pattern 43 may not electrically connect the source electrode 1 to the drain electrode 2.

The shapes of the first conductive patterns 41, the second conductive patterns 42 and the third conductive patterns 43 are not limited, as long as each of them has an effective length in a first direction from the source electrode 1 to the drain electrode 2. The channel region of the active layer 3 may be arranged with a plurality of the first conductive patterns 41, the second conductive patterns 42 and the third conductive patterns 43, or the channel region of the active layer 3 may be arranged with one first conductive pattern 41, one second conductive pattern 42 and one third conductive pattern 43.

In some embodiments of the present disclosure, as shown in FIG. 3, the channel region of the active layer 3 may be arranged with a plurality of the first conductive patterns 41, the second conductive patterns 42 and the third conductive patterns 43 which are arranged in an array form, thereby increasing the electron transportation channels on the channel region and increasing the magnitude of the on-state current of the TFT.

The length of the channel region reduced by the first conductive pattern 41 is related to the effective length of the first conductive pattern 41 in the first direction. Optionally, an extension direction of each of the first conductive patterns 41 is parallel to the first direction from the source electrode 1 to the drain electrode 2, thereby the length of the channel region reduced by the first conductive pattern 41 is equal to the length of the first conductive pattern 41.

As shown in FIG. 4, the length of each of the first conductive patterns 41 is Lx, and an interval between adjacent two first conductive patterns 41 in the first direction is Ly. A plurality of first conductive patterns 41 is arranged at the channel region along the first direction. The number of the intervals between adjacent first conductive patterns 41 in the first direction is m. A vertical distance between the source electrode 1 and the drain electrode 2 is L1. Due to the first conductive patterns 41, the parameter L0 used in calculating the width to length ratio W/L0 of the channel region may be reduced from L1 to m*Ly. Obviously, L0 is reduced significantly. As such, the width to length ratio of the channel region is increased, so the magnitude of the on-state current of the TFT may be increased significantly, and the TFT may easily meet the requirements of the charging rate of the high-PPI display product. Therefore, the width W of channel region of the TFT may be designed to be smaller, thereby reducing the size of the TFT, improving the aperture ratio of the display substrate and reducing the power consumption thereof.

Through massive data validation, when designing the first conductive layer 8, the ratio of Ly to Lx may be designed to be from 0.3 to 0.7. With such parameters, the electronic mobility of the channel region may be increased significantly.

To be specific, the first conductive pattern 41, the second conductive pattern 42 and the third conductive pattern 43 may be nanoscale metallic wires, thereby significantly increasing the electronic mobility of the channel region. A diameter of a cross section of each of the first conductive pattern 41, the second conductive pattern 42 and the third conductive pattern 43 may be smaller than 100 nm, and the length of each of the first conductive pattern 41, the second conductive pattern 42 and the third conductive pattern 43 may be smaller than 1000 nm.

### Embodiment III

A thin film transistor is provided in some embodiments of the present disclosure. As shown in FIG. 5, the thin film transistor includes: a source electrode 1, a drain electrode 2 and an active layer 3 on a base substrate 5, where the active layer 3 includes a source electrode contact region configured to be in contact with the source electrode 1, a drain electrode contact region configured to be in contact with the drain electrode 2 and a channel region between the source electrode contact region and the drain electrode contact region. As shown in FIG. 3, the thin film transistor further includes: a first conductive pattern 41 which is arranged at least at the channel region of the active layer 3 and being in contact with the channel region of the active layer 3; a second conductive pattern 42, being in contact with the source electrode contact region of the active layer 3 and spaced apart from the first conductive pattern 41; and a third conductive pattern 43, being in contact with the drain electrode contact region of the active layer 3 and spaced apart from the first conductive pattern 41.

Because the first conductive pattern 41 is conductive, the first conductive pattern 41 may increase the electron transportation channels on the channel region and increase the electronic mobility of the channel region, thereby significantly shortening the TFT channel and increasing the magnitude of the on-state current of the TFT. As a result, the TFT may easily meet the requirements of the charging rate of the high-PPI display product, so the channel region of the TFT may be designed to be narrower, thereby improving the aperture ratio of the display substrate and reducing the power consumption thereof.

Because the second conductive pattern 42 is conductive, the second conductive pattern 42 at the source electrode contact region may be connected in parallel with the source electrode contact region, thereby reducing the resistance of the source electrode contact region. Because the third conductive pattern 43 is conductive, the third conductive pattern 43 at the drain electrode contact region may be connected in parallel with the drain electrode contact region, thereby reducing the resistance of the drain electrode contact region.

All of the first conductive pattern 41, the second conductive pattern 42 and the third conductive pattern 43 may be arranged on or below the active layer 3, or a part of them is arranged on the active layer 3 and rest is arranged below the active layer 3, as long as being in contact with the channel region of the active layer 3. It should be noted that, the first conductive patterns 41 may be in contact with only a part of the channel region and separated apart from the second conductive pattern 42 and the third conductive pattern 43, such that the first conductive pattern 41, the second conductive pattern 42 and the third conductive pattern 43 may not electrically connect the source electrode 1 to the drain electrode 2.

The shapes of the first conductive patterns 41, the second conductive patterns 42 and the third conductive patterns 43 are not limited, as long as each of them has an effective length in a first direction from the source electrode 1 to the drain electrode 2. The channel region of the active layer 3 may be arranged with a plurality of the first conductive patterns 41, the second conductive patterns 42 and the third conductive patterns 43, or the channel region of the active layer 3 may be arranged with one first conductive pattern 41, one second conductive pattern 42 and one third conductive pattern 43.

In some embodiments of the present disclosure, as shown in FIG. 3, the channel region of the active layer 3 may be arranged with a plurality of the first conductive patterns 41, the second conductive patterns 42 and the third conductive patterns 43 which are arranged in an array form, thereby increasing the electron transportation channels on the channel region and increasing the magnitude of the on-state current of the TFT.

The length of the channel region reduced by the first conductive pattern 41 is related to the effective length of the first conductive pattern 41 in the first direction. Optionally, there is an angle between an extension direction of each of the first conductive patterns 41 and the first direction from the source electrode 1 to the drain electrode 2, and the value of the angle is larger than 0° and smaller than 90°, thereby the length of the channel region reduced by the first conductive pattern 41 is equal to a projection length of the first conductive pattern 41 in the first direction.

As shown in FIG. 6, the projection length of each of the first conductive patterns 41 in the first direction is Lx, and an interval between adjacent two first conductive patterns 41 in the first direction is Ly. A plurality of first conductive patterns 41 is arranged at the channel region along the first direction. The number of the intervals between adjacent first conductive patterns 41 in the first direction is m. A vertical distance between the source electrode 1 and the drain electrode 2 is L1. Due to the first conductive patterns 41, the parameter L0 used in calculating the width to length ratio W/L0 of the channel region may be reduced from L1 to m*Ly. Obviously, L0 is reduced significantly. As such, the width to length ratio of the channel region is increased, so the magnitude of the on-state current of the TFT may be increased significantly, and the TFT may easily meet the requirements of the charging rate of the high-PPI display product. Therefore, the width W of channel region of the TFT may be designed to be smaller, thereby reducing the size of the TFT, improving the aperture ratio of the display substrate and reducing the power consumption thereof.

Through massive data validation, when designing the first conductive layer 8, the ratio of Ly to Lx may be designed to be from 0.3 to 0.7. With such parameters, the electronic mobility of the channel region may be increased significantly.

To be specific, the first conductive pattern 41, the second conductive pattern 42 and the third conductive pattern 43 may be nanoscale metallic wires, thereby significantly increasing the electronic mobility of the channel region. A diameter of a cross section of each of the first conductive pattern 41, the second conductive pattern 42 and the third conductive pattern 43 may be smaller than 100 nm, and the length of each of the first conductive pattern 41, the second conductive pattern 42 and the third conductive pattern 43 may be smaller than 1000 nm.

### Embodiment IV

A display substrate is further provided in some embodiments of the present disclosure, including the above thin film transistor.

### Embodiment V

A display device is further provided in in some embodiments of the present disclosure, including the above display substrate. The display device may be a product or a component with a display function, such as a liquid crystal television, a liquid crystal displayer, a digital photo frame, a cell phone, a tablet PC. The display device further includes a flexible circuit board, a print circuit board and a back plate.

### Embodiment VI

A method of forming a thin film transistor is further provided in some embodiments of the present disclosure, including: forming a source electrode, a drain electrode and an active layer on a base substrate, where the active layer includes a source electrode contact region configured to be in contact with the source electrode, a drain electrode contact region configured to be in contact with the drain electrode and a channel region between the source electrode contact region and the drain electrode contact region; forming a first conductive pattern at least arranged at the channel region of the active layer and being in contact with the channel region of the active layer.

Because the first conductive pattern is conductive, the first conductive pattern may increase the electron transportation channels on the channel region and increase the electronic mobility of the channel region, thereby significantly shortening the TFT channel and increasing the magnitude of the on-state current of the TFT. As a result, the TFT may easily meet the requirements of the charging rate of the high-PPI display product, so the channel region of the TFT may be designed to be narrower, thereby improving the aperture ratio of the display substrate and reducing the power consumption thereof.

Furthermore, in the case that the TFT further includes a second conductive pattern being in contact with the source electrode contact region of the active layer and spaced apart from the first conductive pattern, the method further includes forming the second conductive pattern. In addition, in the case that the TFT further includes a third conductive pattern being in contact with the source electrode contact region of the active layer and spaced apart from the first conductive pattern, the method further includes forming the third conductive pattern.

The first conductive pattern, the second conductive pattern and the third conductive pattern may be formed by a patterning process or an imprinting process.

To be specific, in the case that the first conductive pattern is formed by an imprinting process, the forming the first conductive pattern includes:

Step 1: as shown in FIG. 7, providing a pattern plate 7, and coating a photoresist 6 on the base substrate 5 where the first conductive pattern 41 is to be formed, where the base substrate 5 may be arranged with other components of the TFT already, such as the source electrode 1 and the drain electrode 2, or without other components of the TFT, and the pattern of the pattern plate 7 is the same as the pattern of the first conductive pattern 41 to be formed;

Step 2: as shown in FIG. 8 and FIG. 9, transferring a pattern on a pattern plate 7 onto the photoresist 6 by an imprinting process, to form a photoresist reserved region and a photoresist unreserved region, where the pattern of the photoresist unreserved region is the same as the pattern of the pattern plate 7;

Step 3: as shown in FIG. 10, depositing a conductive layer 8 including a first portion at the photoresist reserved region and a second portion at the photoresist unreserved region and in contact with the base substrate 5, where the conductive layer 8 is made of a metallic material such as AI, Mo and Ti materials or other materials such as a transparent conductive metallic oxide material;

Step 4: as shown in FIG. 11, exposing and developing the photoresist 6, to remove the photoresist 6 at the photoresist reserved region and the first portion of the photoresist 6 and reserve the second portion of the photoresist 6, to form the first conductive pattern 41.

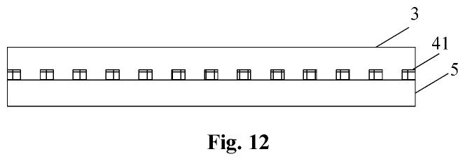

In the case that the first conductive pattern 41 is formed below the active layer 3, and then, as shown in FIG. 12, the active layer 3 may further be formed on the base substrate 5 provided with the first conductive pattern 41. In the case that the first conductive pattern 41 is formed on the active layer 3, the base substrate 5 in Step 1 has been arranged with the active layer 3 already.

According to the method of forming the thin film transistor in some embodiments of the present disclosure, the TFT has the first conductive pattern in contact with the channel region of the active layer. The first conductive pattern may increase the electron transportation channels on the channel region and increase the electronic mobility of the channel region, thereby significantly shortening the TFT channel and increasing the magnitude of the on-state current of the TFT. As a result, the TFT may easily meet the requirements of the charging rate of the high-PPI display product, so the channel region of the TFT may be designed to be narrower, thereby improving the aperture ratio of the display substrate and reducing the power consumption thereof.

Furthermore, in the case that the TFT further includes a second conductive pattern and/or a third conductive pattern, the second conductive pattern and/or the third conductive pattern may be formed simultaneously with the first conductive pattern. In the case that the first conducive patter, the second conductive pattern and/or the third conductive pattern are formed by an imprinting process, the pattern of the pattern plate is the same as the patterns of the first conducive patter, the second conductive pattern and/or the third conductive pattern, therefore it is able to form the second conductive pattern and/or the third conductive pattern simultaneously with the first conductive pattern.

In the method embodiment of the present disclosure, the serial numbers of the steps is not mean to limit the sequence of these steps. Based on these steps, a person skilled in the art may obtain the change the sequence of these steps without any creative effort, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, the terms such as “on” and “below” which represent the relative position relationship among the layer, the film, the region and the substrate, mean that the component may be arranged “directly” on or below another component, or there is an intermediate component therebetween.

The above are merely some embodiments of the present disclosure. A person skilled in the art may make further modifications and improvements without departing from the principle/spirit of the present disclosure, and these modifications and improvements shall also fall within the scope of the present disclosure.

1. A thin film transistor, comprising:
a source electrode, a drain electrode and an active layer on a base substrate, wherein the active layer comprises a source electrode contact region configured to be in contact with the source electrode, a drain electrode contact region configured to be in contact with the drain electrode and a channel region between the source electrode contact region and the drain electrode contact region;
at least one first conductive pattern, arranged at the channel region of the active layer and being in contact with the channel region of the active layer.

2. The thin film transistor according to claim 1, further comprising at least one of:
a second conductive pattern, being in contact with the source electrode contact region of the active layer and spaced apart from the first conductive pattern; and
a third conductive pattern, being in contact with the drain electrode contact region of the active layer and spaced apart from the first conductive pattern.

3. The thin film transistor according to claim 1, wherein a plurality of first conductive patterns is arranged at the channel region of the active layer in an array form.

4. The thin film transistor according to claim 3, wherein an extension direction of each of the first conductive patterns is parallel to a first direction from the source electrode to the drain electrode.

5. The thin film transistor according to claim 4, wherein a length of each of the first conductive patterns is smaller than a vertical distance between the source electrode and the drain electrode.

6. The thin film transistor according to claim 4, wherein the length of each of the first conductive patterns is Lx, and an interval between adjacent two first conductive patterns in the first direction is Ly, and a ratio of Ly to Lx is from 0.3 to 0.7.

7. The thin film transistor according to claim 3, wherein an extension direction of each of the first conductive patterns is not parallel to a first direction from the source electrode to the drain electrode;
a projection length of each of the first conductive patterns in the first direction is Lx, and in an extension direction of each of the first conductive patterns, a projection interval between adjacent two first conductive patterns in the first direction is Ly, and a ratio of Ly to Lx is from 0.3 to 0.7.

8. The thin film transistor according to claim 2, wherein the first conductive pattern, the second conductive pattern and the third conductive pattern are metallic nanowires.

9. The thin film transistor according to claim 1, wherein the length of the first conductive pattern is smaller than 1000 nm.

10. The thin film transistor according to claim 1, wherein a diameter of a cross section of the first conductive pattern is smaller than 100 nm.

11. A display substrate comprising the thin film transistor according to claim 1.

12. A display device comprising the display substrate according to claim 11.

13. A method of forming a thin film transistor, comprising:
forming a source electrode, a drain electrode and an active layer on a base substrate, wherein the active layer comprises a source electrode contact region configured to be in contact with the source electrode, a drain electrode contact region configured to be in contact with the drain electrode and a channel region between the source electrode contact region and the drain electrode contact region;
forming at least one first conductive pattern arranged at the channel region of the active layer and being in contact with the channel region of the active layer.

14. The method according to claim 13, wherein the forming the first conductive pattern further comprises:
coating a photoresist on the base substrate where the first conductive pattern is to be formed;
transferring a pattern on a pattern plate onto the photoresist by an imprinting process, to form a photoresist reserved region and a photoresist unreserved region, wherein the photoresist unreserved region corresponds to the pattern;
depositing a conductive layer including a first portion at the photoresist reserved region and a second portion at the photoresist unreserved region and in contact with the base substrate; and
exposing and developing the photoresist, to remove the photoresist at the photoresist reserved region and the first portion of the photoresist and reserve the second portion of the photoresist, to form the first conductive pattern.

15. The method according to claim 13, further comprising: forming at least one of a second conductive pattern and/or a third conductive pattern simultaneously with the first conductive pattern, wherein the second conductive pattern is in contact with the source electrode contact region of the active layer and spaced apart from the first conductive pattern, and the third conductive pattern is in contact with the drain electrode contact region of the active layer and spaced apart from the first conductive pattern.

16. The thin film transistor according to claim 2, wherein a plurality of first conductive patterns is arranged at the channel region of the active layer in an array form.

17. The method according to claim 14, further comprising: forming at least one of a second conductive pattern and a third conductive pattern simultaneously with the first conductive pattern, wherein the second conductive pattern is in contact with the source electrode contact region of the active layer and spaced apart from the first conductive pattern, and the third conductive pattern is in contact with the drain electrode contact region of the active layer and spaced apart from the first conductive pattern.
